(19) United States
(12) Patent Application Publication
(10) Pub. No.: US 2018/0337079 A1
(43) Pub. Date: Nov. 22, 2018

(54) WAFER BOAT AND PLASMA TREATMENT DEVICE FOR WAFERS

(71) Applicant: CENTROTHERM INTERNATIONAL AG, Blaubeuren (DE)

(72) Inventors: Peter Völk, Griesingen (DE); Uli Walk, Gögglingen (DE); Wolfgang Jooss, Konstanz (DE)

(21) Appl. No.: 15/777,299

(22) PCT Filed: Nov. 17, 2016
(86) PCT No.: PCT/EP2016/077985

§ 371 Date: May 18, 2018

(30) Foreign Application Priority Data
Nov. 18, 2015 (DE) 10 2015 014 903.2

(51) Int. Cl. H01L 21/673; H01L 31/18; H01L 21/687; H01J 37/32; C23C 16/34; C23C 16/505; C23C 16/458

(52) U.S. Cl. CPC H01L 21/67313; H01L 31/1876; H01L 21/68771; H01J 37/32715; H01J 2237/332; H01J 37/32449; C23C 16/345; C23C 16/505; C23C 16/4587; H01J 37/32733

(57) ABSTRACT

The invention relates to a plate element for a wafer boat for the plasma treatment of disk-shaped wafers, in particular semiconductor wafers for semiconductor or photovoltaic applications. The plate element is electrically conductive and has at least one holding unit on each side, for holding a wafer in a wafer holding region. The plate element has at least one recess in at least one side of the plate element and/or at least one opening in the plate element, wherein the at least one recess and/or the at least one opening in the plate element lies at least partially radially outside of the wafer holding region and directly adjacent thereto. The invention further relates to a wafer boat that has a plurality of plate elements of the above type arranged parallel to each other, wherein plate elements arranged adjacent are electrically insulated from each other. The invention further relates to a wafer boat in combination with a plasma treatment device, which has a process chamber for accommodating the wafer boat, means for controlling a process gas atmosphere in the process chamber in an open-loop or closed-loop manner, and at least one voltage source, which can be connected to the electrically conductive plate elements of the wafer boat in a suitable manner in order to apply a voltage between directly adjacent wafers held in the wafer boat.

### RELATED APPLICATIONS

This application corresponds to PCT/EP2018/077985, filed Nov. 17, 2016, which claims the benefit of German Application No. 10 2015 014 903.2, filed Nov. 18, 2015, the subject matter, of which are incorporated herein by reference in their entirety.

### BACKGROUND OF THE INVENTION

The present invention is related to a wafer boat and a treatment apparatus for wafers, which is suitable for generating a plasma between wafers received therein.

In semiconductor and solar cell technology it is well known that disc-shaped substrates made of various materials, which, independently of their geometric shape and material, are referred to as wafers in the following, are exposed to different processes.

In this regard, wafers are frequently exposed to single treatment processes as well as batch processes, that is, processes in which several wafers are treated simultaneously. Both for single processes and for batch processes the wafers must in each case be moved into a desired treatment position. In batch processes this is usually achieved by placing the wafer in so-called boats, which have receptacles for a plurality of wafers. In the boats, the wafers are usually placed parallel to one another. Such boats can be built in various different ways, and frequently the design is such that only the bottom edges of the wafers are received in the boat, such that the wafer stand freely upright. Such boats can for example comprise lead-in chamfers so as to facilitate the placement of the bottom edges of the wafers into the boats. Such boats are usually passive, that is, apart from providing a holding function they have no further function during the processing of the wafers.

In another type of wafer boat, which is for example used for a plasma processing of wafers in the semiconductor or solar cell technology, the wafer boat is formed by a plurality of electrically conductive plates, which are normally made of graphite. The plates are positioned in substance parallel to one another and carrier slits are formed between adjacent plates for receiving wafers. The sides of the plates which face one another each have respective carrier elements for wafers, so that wafers can be received at each of these sides. As carrier elements, usually pins are provided at each plate side which faces another plate, which pins may receive the wafers. In this way, at least two wafers can be completely accommodated in each carrier slit between the plates in such a way that they face each other. Adjacent plates of the wafer boat are electrically isolated from one another, and during the process an AC voltage is applied between directly adjacent plates, usually in the kHz or MHz region. In this way a plasma can be generated between the plates and in particular between the wafers which are held at the respective plates, in order to provide a plasma treatment such as for example a deposition from the plasma or a plasma nitriding of films. For the arrangement of the plates next to one another, spacer elements are used, which have a pre-designated length for adjusting a pre-designated distance between the plates. An example of such a wafer boat, which comprises plates and spacer elements, is described in DE 10 2011 109 444 A1.

As mentioned, a plasma is created not only between adjacent wafers but also between adjacent plates. Due to a usually higher conductivity of the plates compared to the wafers, the plasma between the plates may be denser than between the wafers, which may be detrimental to the process and the homogeneity of the wafer processing. In particular, a stronger effect may occur at the edge region of the wafer compared to ether regions of the wafer. Furthermore, the problem may arise that a backside treatment, especially a backside coating of the wafer may occur, which is also referred to as wrap-around of the coating, which is caused by plasma directly adjacent to the wafer edge.

In order to overcome this problem, in the past, the plates were pre-plated with an insulating layer, for example SiN, in order to attenuate plasma formation between the plates. However, such a pre-plating can in turn lead to other problems and must be renewed regularly, especially after a wet cleaning of the plates in an etching bath, which leads to additional costs.

### SUMMARY OF THE INVENTION

It is therefore an object of the present invention to provide a wafer boat and a plasma processing apparatus for wafers which overcomes or alleviates the above-mentioned problems of wrap-around.

According to the invention, this object is achieved by a plate element according to Claim 1, a wafer boat according to claim 6 and a plasma treatment apparatus according to claim 8. Other embodiments of the invention will inter alia become apparent from the respective dependent claims.

In particular, the is provided a plate element for a wafer boat for the plasma treatment of disk-shaped wafers, wherein the plate element is electrically conductive and has at least one receiving unit for receiving a wafer in a wafer receiving area at each side thereof. According to the invention, the plate element has at least one of at least one recess in at least one side of the plate element and at least one opening in the plate element, wherein at least one of the at least one recess and the at least one opening in the plate element is located at least partially radially outside of the wafer receiving area and directly adjacent thereto. The wafer receiving area is the area that is usually covered by the wafer. A small overlap of recess/opening and wafer, when the wafer is received on the plate element state is possible, but not necessarily wanted. Such a plate element has the advantage that in use may generate an attenuated plasma at the edge region of a received wafer and may thus prevent or at least reduce edge effects and in particular a wrap-around of the plasma.

Preferably, the plate element has a respective recess on both sides of.

In one embodiment, the plate element has at least one recess, which substantially completely encircles the wafer receiving area in. In this context, the term substantially should comprise at least 80%, preferably more than 90% or 95%. This is to ensure that the effect of an attenuated plasma is given substantially at the full circumference of the wafer receiving area.

In an alternative embodiment, the plate element has a plurality of openings, each being located at least partially radially outside of and adjacent to the wafer receiving area. With a large number of openings, it is possible, when sufficient stability is present, to encircle a large circumferential portion of the wafer receiving area. Preferably, the openings in the plate element should radially surround at least 50%, preferably at least 80% of the wafer receiving area.

The wafer boat for the plasma treatment of disk-shaped wafers has a plurality of mutually parallel plate elements of the above type, wherein adjacent plate elements are electrically insulated from each other. Such a wafer boat again enables in use that an attenuated plasma is generated at the edge region of a received wafer and may thus prevent or at least reduce edge effects and in particular a wrap-around of the plasma.

In the case of plate elements having openings, the openings in adjacent plate elements may be offset relative to one another in order to provide the attenuation effect at the full circumference of the wafer receiving area.

The plasma processing apparatus for disc-shaped wafers comprises a process space for housing a wafer boat of the above type, means for controlling or regulating a process gas atmosphere in the process space, and at least one voltage source suitably connectable to the electrically conductive receiving elements of the wafer boat for applying an electrical voltage between directly adjacent wafers received in the wafer boat.

The plasma processing apparatus for wafers comprises a process space for housing a wafer boat of the above type. Further, means for controlling or regulating a process gas atmosphere in the process space, and at least one voltage source are provided, the voltage source being suitably connectable to the electrically conductive receiving elements of the wafer boat for applying an electrical voltage between directly adjacent wafers received in the wafer boat.

### BRIEF DESCRIPTION OF THE DRAWINGS

The invention will be explained in more detail with reference to the drawings; in the drawings:

FIG. 1 shows a schematic side view of a plate element for a wafer boat;

FIG. 2 shows a schematic plan view of the wafer boat according to FIG. 1;

FIG. 3 shows a schematic front view of the wafer boat according to FIG. 1;

FIGS. 4a and 4b show enlarged perspective views of portions of the plate elements of the wafer boat according to FIG. 1;

FIG. 5 shows a schematic view of a plasma treatment device having a wafer boat in accordance with FIG. 1 received therein;

FIG. 6 shows a schematic side view of an alternative plate element;

FIG. 7 shows a schematic side view of another alternative plate element; and

FIG. 8 shows an enlarged perspective partial sectional view of a portion of the plate element of FIG. 6.

### DESCRIPTION

Terms used in the specification, such as top, bottom, left and right, refer to the illustration in the drawings and are not meant to be limiting. However, they may describe preferred embodiments. The wording substantially in relation to parallel, perpendicular or angular data should include deviations of ±3°, preferably ±2°, otherwise substantially refers to at least 80%, preferably at least 90% or 95% of the stated value. Hereinafter, the term wafer is used for disc-shaped substrates, which are preferably semiconductor wafers for semiconductor or photovoltaic applications, however, also substrates of other materials can be provided and processed.

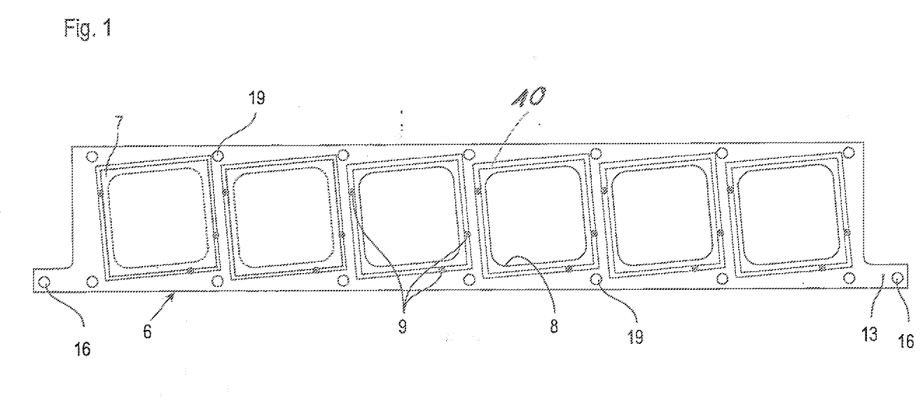

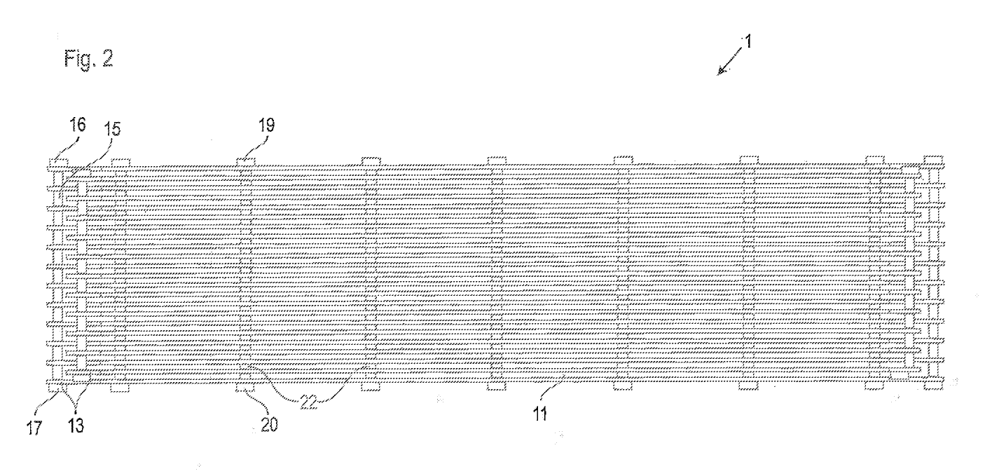

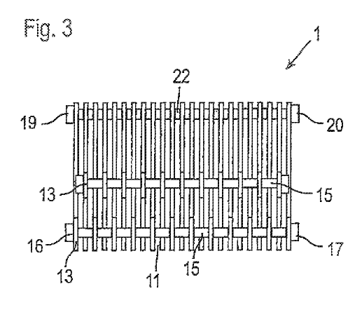

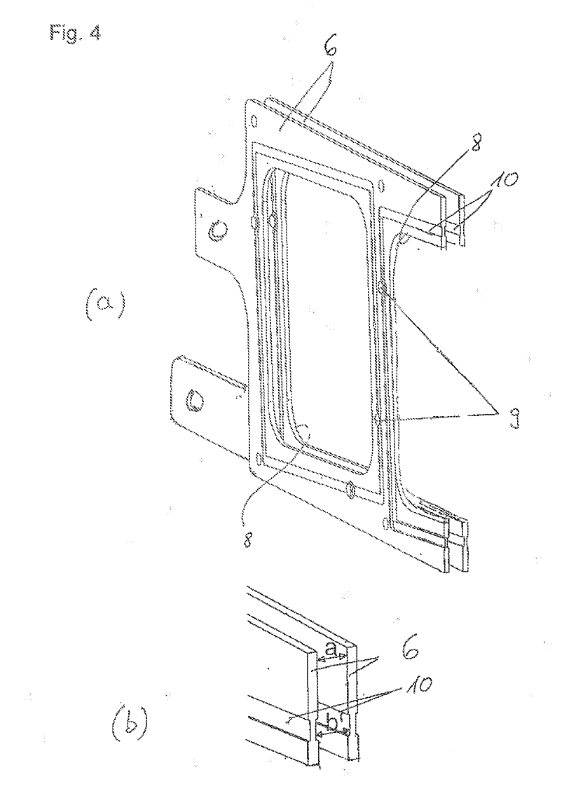

In the following, the basic structure of a wafer boat 1 for use in a plasma treatment apparatus will be explained in more detail with reference to FIGS. 1 to 4, wherein FIG. 1 shows a schematic side view of a plate element of a wafer boat 1, FIGS. 2 and 3 show a plan view and a front view of the wafer boat, and FIGS. 4a and 4b show enlarged perspective views of portions of two adjacent plate elements of the wafer boat. The same reference numerals are used in the figures as far as the same or similar elements are described.

The wafer boat 1 is formed by a plurality of plates 6, which are held together by contacting and clamping units, wherein each plate 6 is suitable for receiving a plurality of wafers 7. The illustrated wafer boat 1 is specifically suitable for a layer deposition from a plasma, for example of Si₃N₄, SIN_{x,} a-Si, Al₂O₃, AlOₓ, doped and undoped polysilicon or amorphous silicon, etc., and is in particular suitable for plasma nitriding of wafers.

The plates 6 are each made of an electrically conductive material, and are in particular formed as graphite plates, wherein depending on the process in which the wafer boat is to be used, a coating or surface treatment of the plate base material can be provided. The plates 6 each have six apertures 8, which are covered by the wafers during the process, as will be explained in more detail herein below. Although six apertures per plate 6 are provided in the illustrated form, it should be noted that a greater or lesser number of apertures may be provided, or the apertures may be completely dispensed with. The plates 6 each have parallel upper and lower edges, (in the upper edge, a plurality of Notches may be formed to allow a position detection of the plates, as described in DE 10 2010 025 483).

In the illustrated embodiment according to FIG. 2, a total of twenty-three plates 6 is provided, wherein the plates 6 are arranged by the respective contacting units and clamping units substantially parallel to each other to form receiving slits 11 therebetween. Twenty-three plates 6 thus form twenty-two of the receiving slits 11. However, in practice, 25, 19 or 21 plates are often used, and the invention is not limited to a certain number of plates 6. Also an even number of plates may be used (e.g. 20, 22, 24, 26, . . . ).

The plates 6 each have—at least on their side(s) facing an adjacent plate 6—groups of three receiving elements 9 each, which receiving elements 9 are arranged so that they can receive a wafer 7 therebetween. Two wafers 7 are shown in the representation according to FIG. 1, as they are accommodated in the two groups of receiving elements 9 on the left. In the other groups, no wafers are received. The groups of the receiving elements 9 are each arranged around a respective one of the recesses 8, as schematically shown in FIG. 1. The groups of the receiving elements 9 each define a wafer receiving area, wherein the term wafer receiving area denotes the area of the plate (including the apertures 8) which is usually covered by a wafer 7 received in a respective group of receiving elements. The wafers 7 can be accommodated in such a way that the receiving elements 9 of a group each contact different side edges of the wafer 7. In the present case, in the longitudinal direction of the plate elements (corresponding to the recesses 8) a total of six groups of receiving elements 9 is provided, each group being able to receive a wafer. In each side of the plate elements 8, a plurality of recesses 10 is provided, each radially arranged with respect to a respective wafer receiving area. The recesses 10 may completely surround the wafer receiving areas, as shown, but it is also possible that the recesses 10 only partially surround the wafer receiving areas. In particular, in the immediate area of the receiving elements 9 the recess 10 may be dispensed with reasons of stability. Preferably, the recesses 10 should, however, substantially completely surround the wafer receiving area, wherein substantially should encompass at least 90% preferably more than 95% of radial encircling of the aperture, wherein optionally a plurality of recesses 10 may be provided per wafer receiving area. Preferably, the recesses 10 are radially directly adjacent to the respective wafer receiving area. However, in view of tolerances, in use there may be a small distance between the wafer receiving area and the recess 10, or to there may be a small overlap of the wafer receiving area and the recess 10.

As can be seen in particular in the view according to FIGS. 4a and 4b, adjacent plates 6 in the wafer boat 1 have a distance a therebetween, which is increased in the region of the depressions 10 to a larger distance b. The depressions 10 of adjacent plates 6 are arranged such that they are aligned with each other. As a result, the distance b is by twice the depth of the recesses 10 larger greater than the distance a.

Although recesses 10 are formed in both sides of the plates in the above description. It would also be conceivable to provide a respective recess 10 in only one side of the plates. In the wafer boat, each side of the plate having a recess 10 would then face e side of an adjacent plate having no recess. This would result in a local increase in the distance a by a single depth of the recess.

At the ends of each plate 6 there is a protruding contact projection 13 which serves for electrically contacting the plates 6, as will be more closely described herein below. Two embodiments of plates 6 are provided, which differ in the position of the contact projections 13. In one embodiment, the contact projections 13 respectively protrude directly adjacent to the bottom edge, whereas in the other embodiment they protrude at a distance from the bottom edge, wherein the distance to the bottom edge is greater than the height of the contact projections 13 of the plates of the other embodiment. The two embodiments of plates 6 are positioned in an alternating manner in the wafer boat 1. As can most clearly be seen in the view according to FIG. 2, the contact projections 13 of directly adjacent plates 6 lie on different height levels of the wafer boat. However, on every second plate 6, the contact projections 13 are on the same height level. Hereby, two spaced contact levels are created by means of the contact projections 13. This arrangement enables directly adjacent plates 6 to be supplied with different potential while every second plate can be supplied with the same potential.

The contact projections 13 which lie on the same contact level are electrically connected by means of contact blocks 15, made of a material of good electrical conductivity. In particular graphite or titanium, and are positioned at a predetermined distance from one another, in the region of the contact projections 13 and in each of the contact blocks 15 at least one through opening is provided. These openings enable the insertion of a clamping element 16 when they are lined up, wherein the clamping element 16 has a shaft section (not visible) and a head section, similar to for example a screw. By means of a counter element, such as a nut 17, which acts on the free end of the shaft section the plates 6 can be fixed to one another. The plates are fixed together in two different groups in such a way that the plates of the different groups are alternating. The clamping element 16 can be made of an electrically conductive material, but this is not obligatory. The contact blocks 15 each preferably have the same length (in the direction which defines the distance between the contact projections 13 of the plates 6), wherein the length should be equal to the width of two carrier slits 11 plus the width of one plate 6.

In addition, further through openings are provided in the plates adjacent to the upper edge and the lower edge, wherein the through openings allow the insertion of a clamping element 19 which has a shaft section (not visible) and a head section, like e.g. a screw. These can in turn again work together with suitable counter elements 20 such as e.g. nuts. In the depicted embodiment, there are seven through openings adjacent to the upper edge and seven through openings adjacent to the lower edge each. Four through openings are positioned, virtually symmetrically around each aperture 8. As a further part of the clamping unit there is provided a plurality of spacer elements 22, which are e.g. provided in the form of spacer sleeves with substantially the same length. The spacer elements 22 are each positioned between directly adjacent plates 6, in particular in the region of the respective through openings.

The respective shaft sections of the clamping elements 19 are sized in such a way that they can extend through corresponding openings of all plates 6 as well as through the spacer elements 22 which are arranged between the plates. In this way, by means of the at least one counter element 20, all plates 6 can be fixed substantially parallel to one another. However, also other clamping units with spacer elements 22 may be used, which arrange and clamp the plates 6 in a substantially parallel manner with the spacer elements 22 being arranged between the plates. In the depicted embodiment, there are 22 carrier slits and in total 14 spacer elements 22 per slit (seven at the upper edge and seven at the tower edge), making a total of 308 spacer elements. The clamping elements are preferably made of an electrically Insulating material, in particular an oxide ceramic, which also applies to the spacer elements 22.

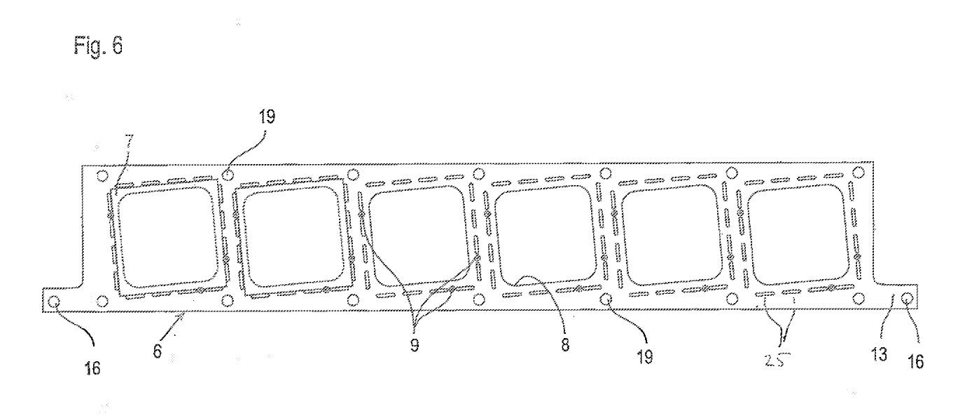

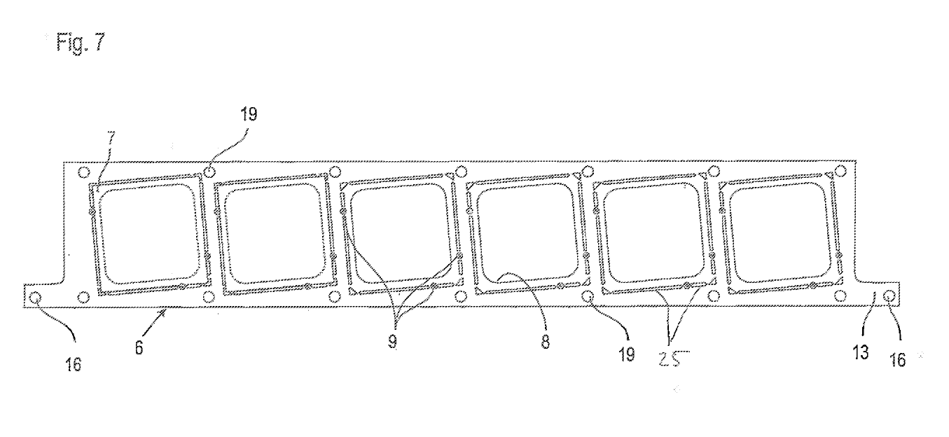

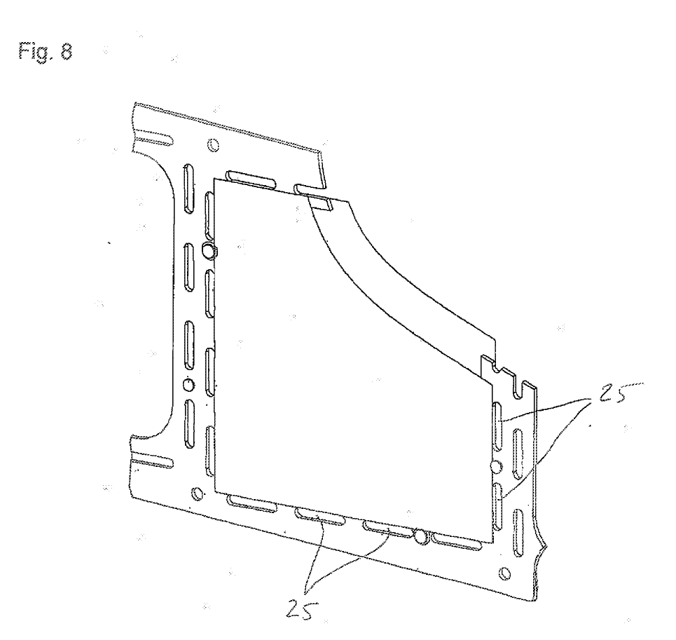

FIGS. 6 to 8 show alternative embodiments of plates 6 which may be used to form a wafer boat 1. FIG. 6 shows a schematic side view, FIG. 8 shows an enlarged perspective partial sectional view of an alternative plate, and FIG. 7 shows a schematic side view of a further alternative plate. Similar to the first embodiment, two wafers 7 are received on the plates 6 as indicated in the side views according to FIGS. 6 and 7. In the view according to FIG. 8, wafers 7 are likewise received on the plate 6, wherein wafers 7 are accommodated on both sides of the plate 6.

The plates 6 are identical to the previously described plates 6 (according to FIGS. 1 to 4) with respect to the material and the basic structure with respect to the apertures 8, receiving elements 9 and projections 13. However, the plates 6 differ in that they have no recesses 10. Rather, in the alternative embodiments, the plates 8 each have a plurality of openings 25 instead of a recess 10. Hereby, a plurality of openings 25 each surrounds a respective wafer receiving area of the plates 6. The openings 25 are preferably radially directly adjacent to the respective wafer receiving area. In view of tolerances, however, in use, a small distance between the wafer receiving area and the openings 25 or a slight overlap of the wafer receiving area and openings 25 may occur.

In each plate 6, a plurality of openings 25 is provided, each radially surrounding a respective wafer receiving area. The openings 25 cannot completely surround the wafer receiving areas, as is the case with the recesses 10, otherwise the wafers could not contact the plates 25. Nevertheless, the openings should preferably surround the wafer receiving areas by at least 90% in the radial direction. The openings 25 have the effect that in a wafer boat adjacent plates 6 have in substance no opposing plate material in a region directly adjacent to the wafer receiving area (preferably in less than 10% of the circumference of the wafer receiving area).

Specifically, in the embodiment according to FIGS. 6 and 8, four identically sized openings 25 are provided along a respective side edge of a wafer receiving area. These openings are equally spaced, such that webs are formed therebetween. In this embodiment, webs are also formed adjacent to the edge regions of the wafer receiving areas. The webs are aligned with the attachment points of the receiving elements 9, which may also be attached to the plates radially outside of the area enclosed by the openings 25. Of course, the number of respective openings 25 may vary and in particular a single opening may also be provided adjacent to the upper edge of the wafer receiving area.

In the embodiment according to FIG. 7, another configuration of openings 25 is shown. In particular, adjacent to the top edge of the wafer receiving area, a single elongated opening 25 is provided which extends substantially the entire length of the top edge. Adjacent to the other side edges of the wafer receiving area, two elongated openings 25 each having different lengths are provided. The web formed between the openings 25 is aligned with the attachment points of the receiving elements 9. Adjacent to the corners of the wafer receiving area, further triangular openings 25 are provided.

As one skilled in the art will appreciate, the arrangement and number of apertures may be varied and it is also possible to combine the different types of apertures and provide the different aperture types on different plates 6 (which are then arranged adjacent to each other in the wafer boat). Preferably, however, the openings 25 should surround the wafer receiving area by at least 90% in the radial direction.

In a particular embodiment, which is not shown, it is possible that the openings 25 surround the wafer receiving areas by a lesser amount, wherein even in this case a radial encircling by at least 50%, in particular by 80% should be provided. In this particular embodiment, the different types of plates 6 of a wafer boat 1 (having bottom/top contact projections 13) which located directly adjacent to each other in the wafer boat 1 are formed such that the openings 25 in one plate 6 are offset from openings 25 of the other plate. In this way, even with a smaller percentage of the radial encircling of the openings 25 with respect to the wafer receiving areas, it may be achieved that in the wafer boat adjacent plates 6 substantially have no opposing plate material in a region directly adjacent to the wafer receiving area (preferably in less than 10% of the circumference of the wafer receiving area).

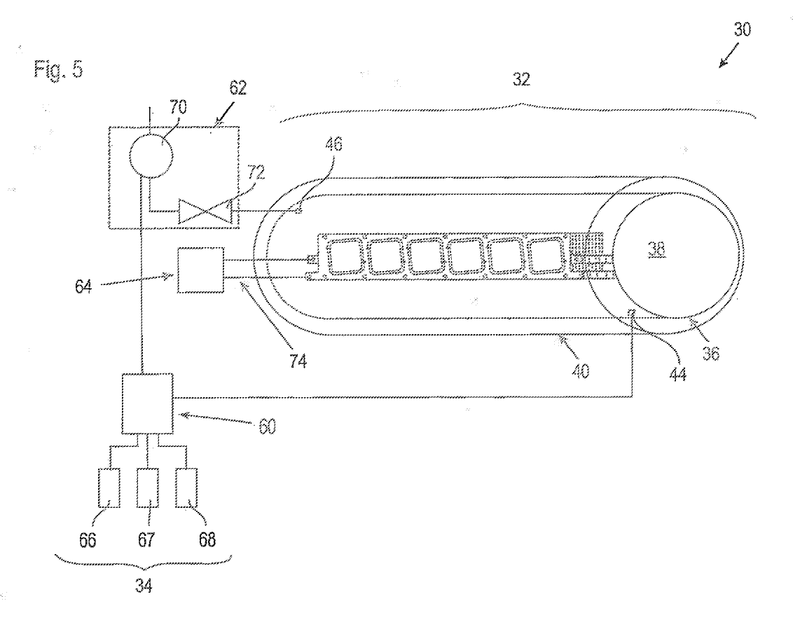

In the following, the basic structure of a plasma treatment device 30, in which a wafer boat 1 of the above type can be used, will now be explained in more detail with reference to FIG. 5, which shows a schematic side view of the treatment device 30.

The treatment apparatus 30 comprises a process chamber section 32 and a control section 34. The process chamber section 32 comprises a tube element 36 which is closed at one end and which forms in its interior a process chamber 38. The open end of the tube element 36 serves for loading the process chamber 38, and the end can be closed and hermetically sealed by means of a closing mechanism (not shown), as is known in this field of technology. The tube element is made of a suitable material which does not introduce impurities into the process, is electrically insulating and can withstand the process conditions with regard to temperature and pressure (vacuum), such as e.g. quartz. At its closed end, the tube element 36 comprises gas-tight passages for the introduction and removal of gases and electricity, which can be designed in the usual manner. Respective supply-lines and discharge-lines could, however, also be situated at the other end or even also at the side at a suitable position between the ends.

The tube element 36 is surrounded by a jacket 40 which insulates the tube element 36 thermally from the environment. Between the jacket 40 and the tube element 36 a heating device is provided (not shown in detail), such as a resistance heater, which is suitable for heating the tube element 36. However, such a heating device can e.g. also be situated in the interior of the tube element 36, or the tube element 36 could itself be designed as a heating element. At the present time, however, an externally located heating element is preferred and, in particular, one which comprises different, individually controllable heating circuits.

In the interior of the tube element 36 are situated carrier elements (not shown in more detail) which form a holding plane for holding a wafer boat 1 (which is only partially shown in FIG. 4), which can e.g. be of the above-described type. The wafer boat can however also be placed in the tube element 36 in such a manner that it stands on the wall of the tube element 36. In this case the wafer boat will be substantially held above the reception plane and is positioned more or less centrally in the tube element, as can be seen e.g. in the front view in FIG. 5. Using suitable carrier elements and/or a direct placement on the tube element, a receiving space is defined in combination with the measurements of the wafer boat, in which is situated a properly inserted wafer boat. The wafer boat can be inserted into and taken from the process chamber 38 as a whole in a loaded state by means of a suitable handling mechanism (not shown). In this case, an electrical contact with at least one contact block 15, respectively, of each of the group of plates 6 will be made, when the wafer boat is loaded, as will be described in more detail hereafter.

In the interior of the tube element 36 carrier elements (not shown in detail) are provided, which form a holding plane for holding a wafer boat 1 (which is only partially shown in FIG. 5), which can e.g. be of the above-described type. The wafer boat can, however, also be placed in the tube element 36 in such a manner that it stands on the wall of the tube element 36. Hereby, the wafer boat will be substantially held above the holding plane and is positioned approximately centrally in the tube element. Using suitable carrier elements and/or a direct placement on the tube element in combination with the dimensions of the wafer boat thus defines a receiving space in which a properly inserted wafer boat will be located. The wafer boat can be inserted into and taken from the process chamber 38 as a whole, i.e. having wafers loaded therein, by means of a suitable handling mechanism (not shown). Hereby, an electrical contact with at least one contact block 15, respectively, of each of the group of plates 6 will be made, as is known in the art.

A lower gas guide tube 44 and an upper guide tube 46 are provided in the interior of the tube element 46, which enable the introduction and exhaustion f gas, respectively. The Gas guide tubes 44, 46 are arranged at diametrically opposite end of the tube element 36 in order to allow the gas to flow through the receiving slits of a wafer boat received therein.

In the following, the control section 34 of the treatment apparatus 36 will be described in more detail. The control section 34 has a gas control unit 60, a negative pressure control unit 62, an electrical control unit 64 and a temperature control unit (not shown in detail), which can all together be controlled by means of a higher-level controller, such as a processor. The temperature control unit is connected to the heating unit (not shown) in order to primarily control or regulate the temperature of the tube element 36 and the process chamber 38, respectively.

The gas control unit 60 is connected with a plurality of different gas sources 66, 67, 68 such as for example gas canisters containing different gases. In the embodiment as shown, three gas sources are shown, although of course any other number of gas sources can be provided. For example, the gas sources can provide di-chlorosilane, tri-chlorosilane, SiH₄, phosphine, borane, di-borane, germane (GeH₄), Ar, H₂, TMA, NH₃, N₂ and other different gases at respective inlets of the gas control unit 60. The gas control unit 60 has two outlets, one of which is connected with the lower gas guide tube 44, and the other of which is connected with a pump 70 of the negative pressure control unit 62. The gas control unit 60 can connect the gas sources in a suitable manner with the outlets and can control the flow of gas, as is well known in this field of technology. Hereby, the gas control unit 60 can direct different gases into the process chamber in particular by means of the lower gas guide tube 44.

The negative pressure control unit 62 basically comprises the pump and a pressure control valve 72. The pump 70 is connected via the pressure control valve 72 with the upper gas guide tube 46 and by means of the pump the process chamber may be pumped to a pre-determined pressure. The conduit from the gas control unit 60 to the pump serves to optionally dilute process gas which is pumped out of the process chamber with N₂.

The electrical control unit 64 comprises at least one voltage source which is suitable for providing at one output thereof at least a high-frequency voltage. The output of the electrical control unit 64 is connected by a cable to a contact unit for the wafer boat in the process chamber. The cable is inserted by means of a suitable vacuum- and temperature resistant passage through the jacket 40 and into the tube element 36.

Herein below, the operation of the plasma treatment apparatus 30 will be described in more detail with reference to the drawings, wherein a plasma-enhanced deposition of silicon nitride or aluminium oxide from a plasma that is excited by 40 kHz is used as an example of a plasma treatment. The treatment apparatus 30 can however also be used for other deposition processes which are plasma-enhanced, wherein the plasma can also be excited by other frequencies, e.g. in the range of 20 kHz to 450 kHz or higher frequencies.

Initially, it will be assumed that a loaded wafer boat 1 of the type described above (according to FIG. 1) is loaded into the process chamber 38, and that the chamber is closed by means of the closing mechanism (not shown). The wafer boat 1 is loaded in such a manner that in each carrier slit 11 there are in total 12 wafers, in the present example in particular silicon wafers, wherein six wafers are provided at each plate 6. The wafers are inserted in such a way that they face each other in pairs, as is known in this field of technology.

In this condition, the interior chamber is at ambient pressure and can e.g. be purged or flooded with N₂ by the gas control unit 60 (in combination with the negative pressure control unit 62).

The tube element 36 and thus the process chamber 38 are heated up by the heating device (not shown), in order to heat the wafer boat 1 and the wafers inserted therein to a pre-determined temperature which is advantageous for the process.

When the pre-determined temperature of the wafer boat 1 and thus the entire unit (wafer boat 1, wafers and tube element 36) is reached, the process chamber may be pumped to a pre-determined negative pressure by the negative pressure control unit 82. When the pre-determined negative pressure is reached, a desired process gas, such as e.g. SiH₄/NH₃ for a silicon nitride deposition, in defined proportions, which may be dependent on the desired coating properties, is introduced by means of the gas control unit 60, while the negative pressure is maintained by the negative pressure control unit 62 by pumping out the introduced process gas. The process gas pumped out by the pump 70 may be diluted with N₂ at this point in time, as is known in this field of technology. For this purpose, N₂ is added by means of the gas control unit 60 and the appropriate conduit to the pump.

By means of the electrical control unit 64, a high-frequency voltage with a frequency of 40 kHz is applied to the wafer boat 1. This results in a plasma ignition of the process gas between the plates 6 and in particular between the wafers loaded into the wafer boat 1 and a plasma-enhanced silicon nitride deposition occurs on the wafers. Hereby, in the region of the recesses 10 in the plate elements 6, the plasma formed between the plates is locally attenuated due to the Increased distance. Thus, the plasma directly adjacent to the edge region of the wafers (radially outward of the wafer) is attenuated, i.e. it is locally less dense than in other areas between the plates 6. Hereby, edge effects and in particular a backside deposition (wrap-around) can be prevented or at least reduced.

A corresponding effect of attenuating the plasma also results when using the plates 6 having the openings 25, since in the region of the openings 25, the plasma between the plates is strongly attenuated. The effect may be stronger than with the recesses.

The gas flow is kept constant during the deposition process, in order to avoid a local depletion of the active components of the process gas. After a sufficient deposition time for the requisite layer thickness, the electrical control unit is again deactivated, and the gas supply is stopped, or switched back to supplying N₂ in order to purge the process chamber 38 and to optionally ventilate the same (returning to atmospheric pressure). Finally, the process chamber 38 can then be brought back to environmental pressure.

As can be seen from the above description, the wafer boat 1 of the above type offers the advantage that an attenuated plasma is generated at an edge region (radially outside of) the wafer.

The plates 6, the treatment device 30 and the wafer boat 1 have been explained in detail with reference to certain embodiments of the Invention with reference to the drawing, without being limited to the embodiments specifically shown. In particular, the plates 6 of the wafer boat 1 could have other dimensions and be sized to accommodate a different number of wafers.

1-8. (canceled)

9. Plate element for a wafer boat for the plasma treatment of disc-shaped wafers, wherein the plate element is electrically conductive and has at least one receiving unit for receiving a wafer in a wafer receiving area at each side thereof wherein the plate element comprises at least one of at least one recess in at least one side of the plate element and at least one opening in the plate element, wherein at least one of the at least one recess and the at least one opening in the plate element is located at least partially radially outside of the wafer receiving area and directly adjacent thereto.

10. The plate element according to claim 9, wherein the plate element has a respective recess on both sides.

11. The plate element according to claim 9, wherein the recess substantially completely surrounds the wafer receiving area.

12. The plate element according to claim 9, wherein the plate element has a plurality of openings each lying at least partially radially outside of the wafer receiving area and adjacent thereto.

13. The plate element according to claim 9, wherein the openings in the plate element radially encircle at least 50%, of the wafer receiving area.

14. The plate element according to claim 9, wherein the openings in the plate element radially encircle at least 80% of the wafer receiving area.

15. A Wafer boat for the plasma treatment of disk-shaped wafers, in particular semiconductor wafers for semiconductor or photovoltaic applications, comprising:
a plurality of mutually parallel plate elements according to claim 9, wherein adjacently located plate elements are electrically insulated from each other.

16. The wafer boat according to claim 9, wherein openings in adjacent plate elements are offset from each other.

17. A plasma processing apparatus for disc-shaped wafers, in particular semiconductor wafers, comprising:
a process space for housing a wafer boat according to any one of the preceding claims;
means for controlling or regulating a process gas atmosphere in the process space; and
at least one voltage source suitably connectable to the electrically conductive receiving elements of the wafer boat for applying an electrical voltage between directly adjacent wafers received in the wafer boat.

18. The plate element according to claim 9, wherein the disc-shaped wafers comprise semiconductor wafers for semiconductor or photovoltaic applications.
